(19) United States
(12) Patent Application Publication
(10) Pub. No.: US 2024/0388064 A1
(43) Pub. Date: Nov. 21, 2024

(54) OPTICAL SEMICONDUCTOR ELEMENT, OPTICAL MODULE, AND METHOD FOR MANUFACTURING OPTICAL SEMICONDUCTOR ELEMENT

(71) Applicant: Mitsubishi Electric Corporation, Tokyo (JP)

(72) Inventor: Eiji NAKAI, Tokyo (JP)

(73) Assignee: Mitsubishi Electric Corporation, Tokyo (JP)

(21) Appl. No.: 18/579,952

(22) PCT Filed: Sep. 28, 2021
(86) PCT No.: PCT/JP2021/035516

§ 371 Date: Jan. 17, 2024

(51) Int. Cl. H01S 5/227; H01S 5/02253; H01S 5/0231; H01S 5/042; H01S 5/20

(52) U.S. Cl. CPC H01S 5/2275; H01S 5/02253; H01S 5/0231; H01S 5/0421; H01S 5/2009

(57) ABSTRACT

An optical semiconductor element comprising: a substrate; a mesa in which a part of a first cladding layer at least, an active layer, and a second cladding layer that are sequentially stacked on the substrate; an electron barrier layer formed on both side surfaces of the mesa so as to cover at least side surfaces of the active layer and the second cladding layer, the electron barrier layer with respect to the active layer; a semi-insulating high resistance buried layer formed on both sides of the mesa so as to bury the mesa and the electron barrier layer; and a contact layer formed on the second cladding layer. The high resistance buried layer formed on both the sides of the mesa is a continuous member, and a lower surface of the high resistance buried layer is in contact with the substrate or the first cladding layer.

### TECHNICAL FIELD

The present disclosure relates to an optical semiconductor element used for optical communication, an optical module, and a method for manufacturing the optical semiconductor element.

### BACKGROUND ART

In an optical semiconductor element such as a semiconductor laser used for optical communication, a high resistance buried layer is formed on both sides of a mesa including an active layer so as to bury the mesa. Among such optical semiconductor elements, there is an optical semiconductor element in which an electron barrier layer is provided from a side surface of a mesa to a top surface of a substrate in order to suppress a leakage current (for example, refer to Patent Document 1). The electron barrier layer suppresses a leakage current flowing between the mesa and the high resistance buried layer.

### CITATION LIST

### Patent Document

Patent Document 1: Japanese Patent Application Laid-Open No. 2015-050202

### SUMMARY OF INVENTION

### Problems to be Solved by Invention

However, in the above-described optical semiconductor element, the modulation speed of the laser is limited. In the above-described optical semiconductor element, the electron barrier layer is also formed on the top surface of the substrate. A parasitic capacitance is generated between the electron barrier layer formed on the top surface of the substrate and the substrate. This parasitic capacitance limits the modulation speed of the laser.

The present disclosure has been made to solve the above-described problem, and an object thereof is to obtain an optical semiconductor element and an optical module that are capable of high-speed operation while a leakage current is suppressed, and a method for manufacturing the optical semiconductor element.

### Means for Solving Problems

An optical semiconductor element according to the present disclosure comprising: a substrate; a mesa in which a part of a first cladding layer at least, an active layer, and a second cladding layer that are formed on the substrate and stacked in this order from below; an electron barrier layer formed on both side surfaces of the mesa so as to cover at least side surfaces of the active layer and the second cladding layer, the electron barrier layer serving as an electron barrier with respect to the active layer; a semi-insulating high resistance buried layer formed on both sides of the mesa so as to bury the mesa and the electron barrier layer; and a contact layer formed on the second cladding layer. The high resistance buried layer formed on both the sides of the mesa is a continuous member, and a lower surface of the high resistance buried layer is in contact with the substrate or the first cladding layer.

Further, an optical module according to the present disclosure comprising: a stem; a lead pin passing through the stem; a carrier fixed to the stem; the above-described optical semiconductor element that is fixed to the carrier and is electrically connected to the lead pin; and a lens cap that includes a lens that condenses laser light emitted from the optical semiconductor element to emit the laser light outside and a cylindrical cap to fix the lens and in which the cap is fixed to the stem so as to enclose the carrier and the optical semiconductor element.

A method for manufacturing an optical semiconductor element according to the present disclosure comprising: a step of stacking a first cladding layer, an active layer, and a second cladding layer on a substrate in this order; a step of forming a mesa by etching both sides of a location where the mesa is to be formed from a top surface of the second cladding layer to the substrate is exposed or to a middle of the first cladding layer; a step of forming a semi-insulating first high resistance buried layer on a top surface of the substrate or a top surface of the first cladding layer exposed by the etching on both sides of the mesa such that an upper end of the first high resistance buried layer on a side surface of the mesa does not extend beyond a lower end of the active layer; a step of forming an electron barrier layer serving as an electron barrier with respect to the active layer on both side surfaces of the mesa that are exposed; a step of forming a second high resistance buried layer having the same material and composition as those of the first high resistance buried layer on the first high resistance buried layer so as to bury the mesa and the electron barrier layer; and a step of forming a contact layer on the second cladding layer.

### Effect of Invention

According to the present disclosure, since the electron barrier layer is formed on the side surfaces of the mesa, the high resistance buried layer on both sides of the mesa is a continuous member, and the lower surface of the high resistance buried layer is in contact with the substrate or the first cladding layer, it is possible to obtain an optical semiconductor element capable of high-speed operation while a leakage current is suppressed.

### BRIEF DESCRIPTION OF DRAWINGS

FIG. 1 is a cross-sectional view of an optical semiconductor element according to Embodiment 1.

FIG. 2 is a cross-sectional view of a variation of an optical semiconductor element according to Embodiment 1.

FIG. 3 is a cross-sectional view of a comparative example of an optical semiconductor element according to Embodiment 1.

FIG. 4 is a cross-sectional view of a comparative example of an optical semiconductor element according to Embodiment 1.

FIG. 5 is a cross-sectional view showing a method for manufacturing the optical semiconductor element according to Embodiment 1.

FIG. 6 is a cross-sectional view showing the method for manufacturing the optical semiconductor element according to Embodiment 1.

FIG. 7 is a cross-sectional view showing the method for manufacturing the optical semiconductor element according to Embodiment 1.

FIG. 8 is a cross-sectional view showing the method for manufacturing the optical semiconductor element according to Embodiment 1.

FIG. 9 is a cross-sectional view showing the method for manufacturing the optical semiconductor element according to Embodiment 1.

FIG. 10 is a cross-sectional view showing the method for the manufacturing the optical semiconductor element according to Embodiment 1.

FIG. 11 is a cross-sectional view of an optical semiconductor element according to Embodiment 2.

FIG. 12 is a cross-sectional view of an optical module according to Embodiment 3.

### MODES FOR CARRYING OUT INVENTION

### Embodiment 1

A configuration of an optical semiconductor element 10 according to Embodiment 1 will be described.

The optical semiconductor element 10 according to Embodiment 1 is a semiconductor laser for optical communication using a group III-V compound. Group III elements include B, Al, Ga, In, and the like. Group V elements include N, P, As, Sb, and the like. A typical III-V compound include GaAs, GaN, InP, and the like.

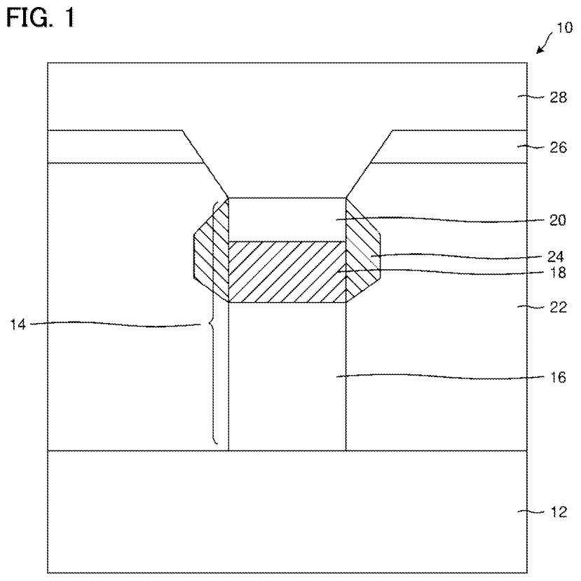

FIG. 1 is a cross-sectional view of an optical semiconductor element 10 according to Embodiment 1. The cross section of FIG. 1 corresponds to a plane perpendicular to the emission direction of laser light.

The optical semiconductor element 10 according to Embodiment 1 includes a substrate 12. The substrate 12 is made of n-type InP doped with S.

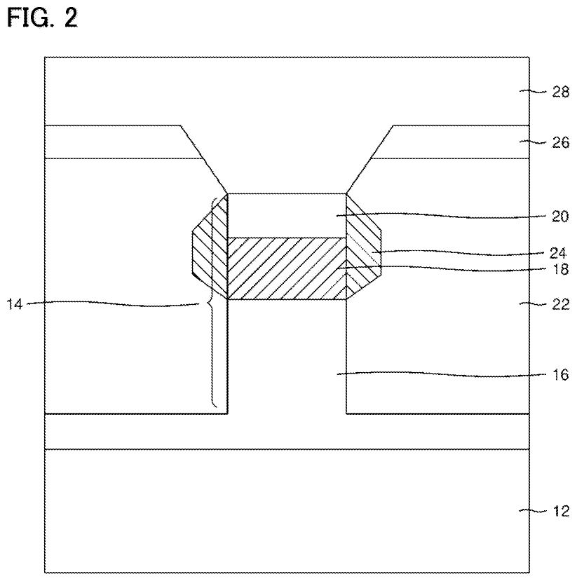

A mesa 14 is formed on the substrate 12. The mesa 14 has a mesa shape as shown in FIG. 1 and extends in a direction perpendicular to the plane of the paper in FIG. 1. In the mesa 14, a first cladding layer 16 formed on the substrate 12, an active layer 18, and a second cladding layer 20 are stacked in this order from below. The mesa 14 has a structure in which light generated in the active layer 18 is confined from above and below by the first cladding layer 16 and the second cladding layer 20. The first cladding layer 16 is made of the n-type InP doped with S, is 0.5 to 2 μm thick, and has a carrier concentration of 1×10¹⁸ to 8×10¹⁸ cm⁻³. The first cladding layer 16 may include a buffer layer or an optical guide layer. The active layer 18 is made of undoped AlGaInAs or InGaAsP and has a thickness of 0.05 to 0.2 μm. The second cladding layer 20 is made of p-type InP doped with Zn, is 0.5 to 2 μm thick, and has a carrier concentration of 1×10¹⁸ to 2×10¹⁸ cm⁻³. The second cladding layer 20 may include the buffer layer or the optical guide layer. Note that the mesa 14 may have the entire first cladding layer 16 as shown in FIG. 1, or may have a part of the first cladding layer 16 as shown in FIG. 2. That is, the mesa 14 may have at least a part of the first cladding layer 16 formed on the substrate 12.

An electron barrier layer 24 is formed on both side surfaces of the mesa 14. The electron barrier layer 24 is made of the p-type InP doped with Zn, is 0.05 to 2 μm thick in the lateral direction, and has a carrier concentration of 2×10⁷ cm⁻³ or more. The electron barrier layer 24 serves as an electron potential barrier with respect to the active layer 18. The electron barrier layer 24 is formed so as to cover at least the side surfaces of the active layer 18 and the second cladding layer 20. A lower end of the electron barrier layer 24 on the side surface of the mesa 14 may be located at a position equal to or lower than a lower end of the active layer 18. However, in order to suppress an absorption loss and parasitic capacitance, it is desirable that the lower end of the electron barrier layer 24 on the side surface of the mesa 14 should be in a range from the lower end of the active layer 18 to a position 0.5 μm lower than the lower end of the active layer 18.

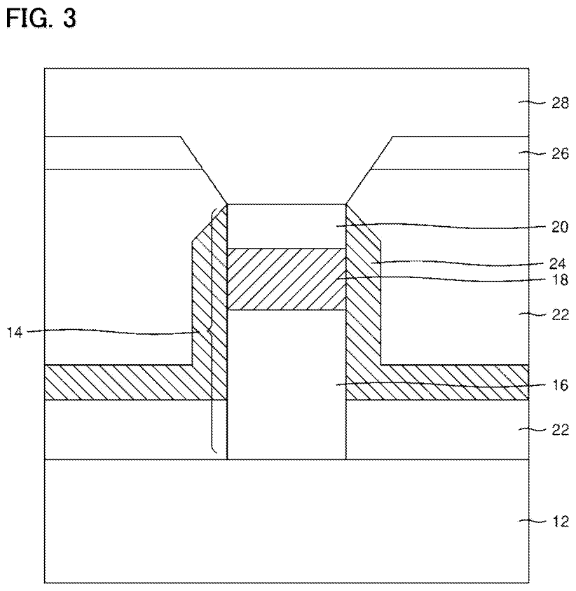

A high resistance buried layer 22 is formed on both sides of the mesa 14 so as to bury the mesa 14 and the electron barrier layer 24. The high resistance buried layer 22 formed on both the sides of the mesa 14 is a continuous member, and the lower surface of the high resistance buried layer 22 is in contact with the substrate 12. Here, the continuous member refers to a member that is not divided by another substance and is integrated. For example, as shown in FIG. 3, if the electron barrier layer 24 separates the high resistance buried layer 22 into upper and lower portions, the high resistance buried layer 22 are not a continuous member. The high resistance buried layer 22 is made of semi-insulating InP doped with Fe or Ru, and an impurity concentration of Fe or Ru is 6×10¹⁶ cm⁻³ or more. Note that, when the optical semiconductor element has the structure shown in FIG. 2, the lower surface of the high resistance buried layer 22 is in contact with the first cladding layer 16.

The carrier concentration of the electron barrier layer 24 is preferably set to 2×10¹⁷ cm⁻³ or more in consideration of interdiffusion between Fe or Ru in the high resistance buried layer 22 and Zn in the electron barrier layer 24. Since the concentration of the interdiffusion is determined by the layer having a lower active concentration among the electron barrier layer 24 and the high resistance buried layer 22, the amount of Zn flowing out to the high resistance buried layer 22 is about 1×10¹⁷ cm⁻³ or less, which is the active concentration of Fe or Ru. In consideration of this, it is desirable to set the carrier concentration of the electron barrier layer 24 to 2×10¹⁷ cm⁻³ or more.

When the high resistance buried layer 22 is formed in this manner, electrons directed from the substrate 12 toward the contact layer 28 flow intensively to the mesa 14. The high resistance buried layer 22 is semi-insulating and has a higher resistivity than the first cladding layer 16. Further, it is doped with Fe or Ru, and thus Fe or Ru being in a deep acceptor level traps electrons. Therefore, electrons flowing from the substrate 12 toward the contact layer 28 flow intensively to the mesa 14.

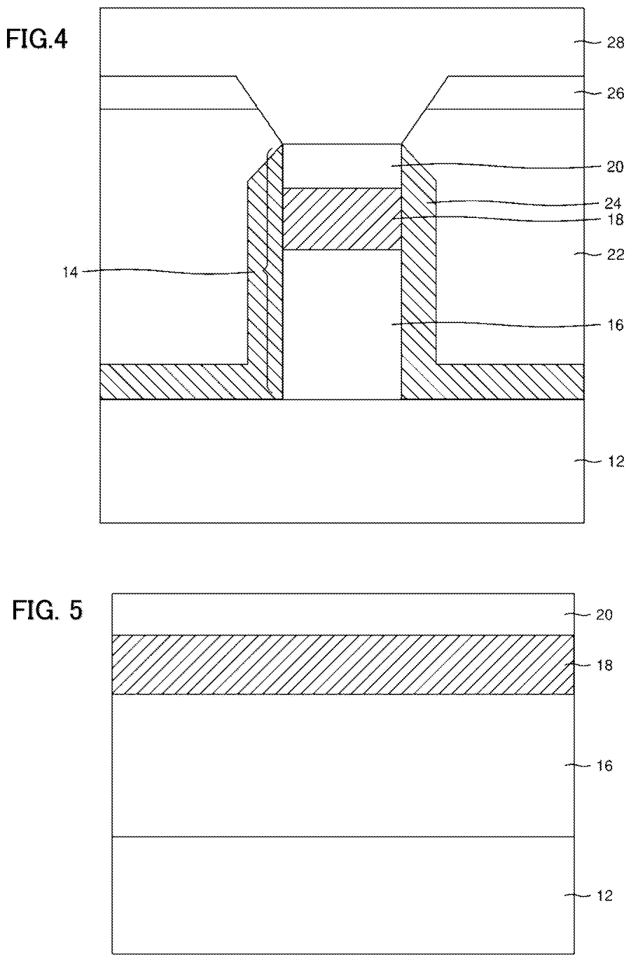

When the high resistance buried layer 22 formed on both the sides of the mesa 14 is the continuous member, the parasitic capacitance between the electron barrier layer 24 and the substrate 12 is reduced as compared with the case where the high resistance buried layer 22 is separated by the electron barrier layer 24 (FIG. 3). Further, when the lower surface of the high resistance buried layer 22 is in contact with the substrate 12 or the first cladding layer 16, the parasitic capacitance between the electron barrier layer 24 and the substrate 12 is reduced as compared with the case where the electron barrier layer 24 is also formed under the high resistance buried layer 22 (FIG. 4).

Since the electron barrier layer 24 is formed on the side surface of the mesa 14, a leak path between the active layer 18 and the high resistance buried layer 22 is not formed. If the electron barrier layer 24 is not provided, Zn in the second cladding layer 20 or the contact layer 28 and Fe or Ru in the high resistance buried layer 22 are interdiffused, and a p-InP region having a low carrier concentration of 1×10¹⁷ cm⁻³ or less is formed in the high resistance buried layer 22. In the p-InP region having the low carrier concentration, the electron barrier is lowered. When the electron barrier is lowered in this manner, electrons leak from the p-InP region having the low carrier concentration. In contrast, since the electron barrier layer 24 is formed in this embodiment, no leak path is formed.

Referring back to FIG. 1, a hole barrier layer 26 is formed on the high resistance buried layer 22. The hole barrier layer 26 is made of n-type InP doped with S, Si, or Sn, is 0.1 to 0.5 μm thick, and has a carrier concentration of 2×10¹⁸ cm⁻³ or more. Since the hole barrier layer 26 is made of the n-type InP, the hole barrier layer 26 serves as a hole potential barrier with respect to the contact layer 28 made of p-type InP to be described later. Therefore, leakage of holes from the contact layer 28 to the high resistance buried layer 22 is suppressed. Note that, although the hole barrier layer 26 is formed apart from the mesa 14 in FIG. 1, it may be in contact with the upper end of the mesa 14.

The contact layer 28 is formed on the second cladding layer 20, the high resistance buried layer 22, and the hole barrier layer 26. As shown in FIG. 1, the hole barrier layer 26 is formed between the high resistance buried layer 22 and the contact layer 28. The contact layer 28 is made of the p-type InP doped with Zn, is 1 to 3 μm thick, and has a carrier concentration of 1×10¹⁸ to 2×10¹⁸ cm⁻³. In order to improve the ohmic property with a metal electrode (not shown) to be formed on the contact layer 28, an InGaAs layer or an InGaAsP layer, heavily doped with Zn, may be thinly inserted on the surface of the contact layer 28. Note that the contact layer 28 should be provided at least on the second cladding layer 20.

A method for manufacturing the optical semiconductor element 10 according to Embodiment 1 will be described. Although a metal organic chemical vapor deposition method, a molecular beam epitaxy method, or the like may be used for semiconductor growth in each manufacturing step, a description will be made on the assumption that the metal organic chemical vapor deposition method is used.

First, as shown in FIG. 5, the first cladding layer 16, the active layer 18, and the second cladding layer 20 are stacked on the substrate 12 in this order. The growth temperature of each layer is 550 to 700 degrees C.

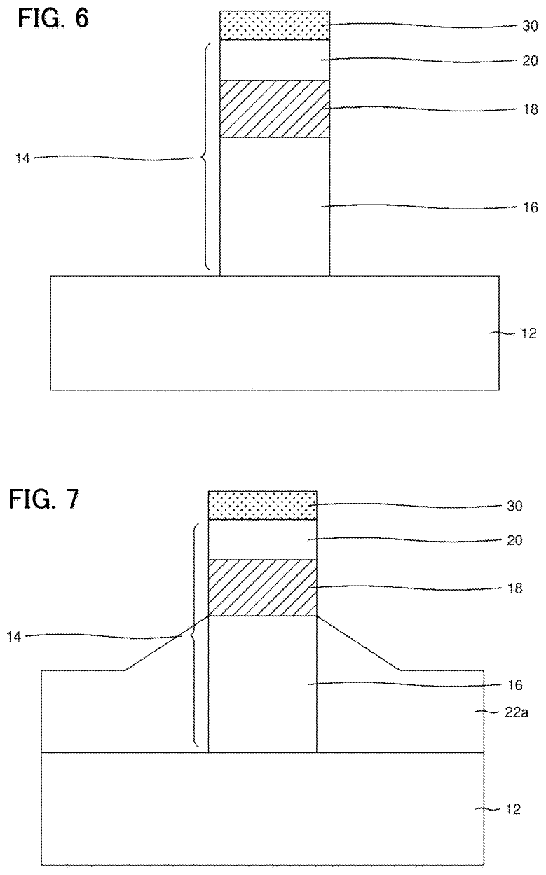

Next, as shown in FIG. 6, the mesa 14 is formed. In order to form the mesa 14, first, a SiO₂ mask 30 is formed using a sputtering apparatus. It is formed on the second cladding layer 20 where the mesa 14 is to be formed. Next, using an inductively coupled plasma (ICP) apparatus, both sides of the mask 30 are etched from the top surface of the second cladding layer 20 to the substrate 12 is exposed. The mesa 14 is formed by this etching. Note that the etching may be stopped in the middle of the first cladding layer 16 to form the mesa 14 having the structure shown in FIG. 2.

Next, as shown in FIG. 7, a first high resistance buried layer 22a is formed on the top surface of the substrate 12 exposed by the etching on both sides of the mesa 14. The growth temperature of the first high resistance buried layer 22a is 600 degrees C. or higher. The first high resistance buried layer 22a is formed such that the top end on the side of the mesa 14 does not exceed the lower end of the active layer 18. FIG. 7 shows a case where the top end of the first high resistance buried layer 22a is located at the lower end of the active layer 18. The mask 30 used to form the mesa 14 can be used as a selective growth mask. During the growth of the first high resistance buried layer 22a, a halogen-based gas for etching such as HCl may be simultaneously supplied in addition to a group III gas and a group V gas that are raw material gases. By simultaneously supplying the halogen-based gas for etching, the growth rate of a (111) plane can be reduced, and the growth of abnormal protrusion in a <111> direction in the first high resistance buried layer 22a can be prevented. In addition, the growth rate on the side surface of the mesa 14 can be reduced. Note that, in order to suppress the growth of the abnormal protrusion, the mask 30 may be made wider than the mesa 14 before the growth of the first high resistance buried layer 22a. Further, when the etching of the first cladding layer 16 is stopped before the substrate 12 is exposed in the step of forming the mesa 14, the first high resistance buried layer 22a may be formed on the top surface of the first cladding layer 16 exposed by the etching.

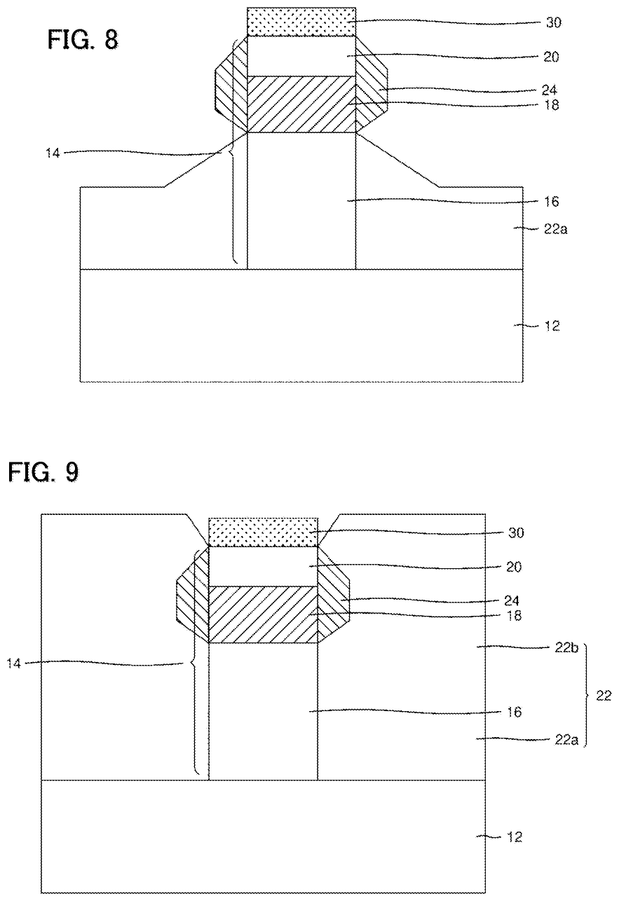

Next, as shown in FIG. 8, the electron barrier layer 24 is formed on both side surfaces of the exposed mesa 14. At this time, the growth temperature is lowered and the flow rate of the group III gas is increased so that the growth rate of the (1−10) plane on the side surface of the mesa 14 is higher than that of the (001) plane that is the top surface of the first high resistance buried layer 22a. Specifically, it is desirable that the growth temperature should be set to 500 to 600 degrees C. and the flow rate of trimethylindium (TMIn), which is one of the raw material gases, should be set to 2×10⁻⁴ mol/min or more. Under such conditions, a migration length of a supplied raw material (distance required for crystallization by surface diffusion) is reduced. When the migration length becomes short, the raw material component supplied from above the mask 30 is desorbed before reaching the (001) plane or crystallized on the side surface of the mesa 14. Therefore, the growth rate of the (1−10) plane is faster than that of the (001) plane, and deposition of the deposits on the top surface of the first high resistance buried layer is reduced. Note that, when the electron barrier layer 24 is formed, the halogen-based gas for etching such as HCl may be supplied in addition to the raw material gas. By supplying the halogen-based gas for etching, it is possible to prevent deposition of the deposits on the top surface of the first high resistance buried layer.

If a step of removing a natural oxide film formed on the side surface of the active layer 18 by simultaneously supplying the group V gas and the halogen-based gas for etching such as HCl before the step of forming the first high resistance buried layer 22a or before the step of forming the electron barrier layer 24, the electron barrier layer 24 can be formed more stably. These gases may be supplied in both the step of forming the first high resistance buried layer 22a and the step of forming the electron barrier layer 24.

In order to increase the accuracy of the position where the electron barrier layer 24 is formed, it is desirable to measure the height of the mesa 14 after the formation of the mesa 14 and adjust the growth time of the first high resistance buried layer 22a.

Next, the deposits deposited on the first high resistance buried layer 22a when the electron barrier layer 24 is formed is removed. In order to remove the deposits, the halogen-based gas for etching such as HCl and the group V gas being the same as that supplied as the raw material gas for the first high resistance buried layer 22a when the first high resistance buried layer 22a is formed are simultaneously supplied. By supplying the group V gas, deterioration of surface morphology of the first high resistance buried layer 22a can be suppressed. Note that, when the electron barrier layer 24 is formed, if there is no growth on the (001) plane, which is the top surface of the first high resistance buried layer 22a, it is not necessary to perform the process for removing the deposits.

Next, as shown in FIG. 9, a second high resistance buried layer 22b is formed on the first high resistance buried layer 22a so as to bury the mesa 14 and the electron barrier layer 24. The second high resistance buried layer 22b is made of the same material and composition as the first high resistance buried layer 22a. The method and conditions for forming the second high resistance buried layer 22b may be the same as those for forming the first high resistance buried layer 22a. In this way, the high resistance buried layer 22 is formed with the combination of the first high resistance buried layer 22a and the second high resistance buried layer 22b. Note that, in order to suppress the growth of the abnormal protrusion in the first high resistance buried layer 22a and the second high resistance buried layer 22b, it is desirable that the growth temperature of the first high resistance buried layer 22a and the second high resistance buried layer 22b should be equal to or higher than the growth temperature of the electron barrier layer 24.

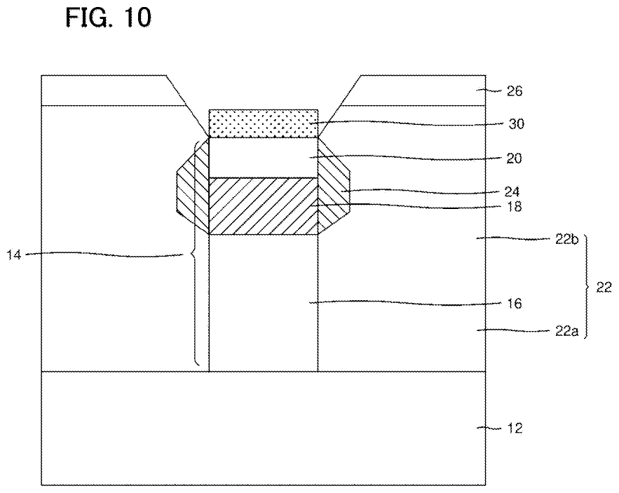

Next, as shown in FIG. 10, the hole barrier layer 26 is formed on the high resistance buried layer 22. The growth temperature is 500 to 600 degrees C.

When the high resistance buried layer 22 grows higher than the mesa 14 at the state where the formation of the second high resistance buried layer 22b is completed (FIG. 9), a (111) B plane is formed on the top surface of the high resistance buried layer 22. Since the growth rate on the (111) B plane is extremely low, the tip position of the hole barrier layer 26 in FIG. 10 is far away from the mesa 14. Then, holes from the contact layer 28 may leak to the high resistance buried layer 22. In order to prevent this, it is desirable that the film thickness of the high resistance buried layer 22 should be adjusted in accordance with the height of the mesa 14 to reduce the area of the (111) B plane of the high resistance buried layer 22. Alternatively, it is desirable to reduce the area of the exposed (111) B plane of the high-resistance embedded layer 22 in the state shown in FIG. 10 by increasing the growth rate of the hole barrier layer 26 on the (111) B plane through the adjustment of the growth conditions of the hole barrier layer 26.

Next, after the mask 30 is removed, the contact layer 28 is formed on the second cladding layer 20, the second high resistance buried layer 22b, and the hole barrier layer 26. The growth temperature is 550 to 700 degrees C. By forming the contact layer 28, the optical semiconductor element 10 shown in FIG. 1 is obtained.

As described above, in the optical semiconductor element 10 according to this embodiment, since the electron barrier layer 24 is formed on the side surfaces of the mesa 14, the leakage current between the active layer 18 and the high resistance buried layer 22 is suppressed. The reason is twofold. The first reason is that the electron barrier layer 24 serves as the electron barrier with respect to the active layer 18 to suppress electrons in the active layer 18 from leaking to the high resistance buried layer 22. The second reason is that the leak path between the active layer 18 and the high resistance buried layer 22 is not formed, and thus the leak current is suppressed.

In addition, since the high resistance buried layer 22 on both the sides of the mesa 14 is the continuous member and the lower surface of the high resistance buried layers 22 is in contact with the substrate 12 or the first cladding layer 16, high-speed operation is possible. As described above, when the high resistance buried layer 22 on both the sides of the mesa 14 is the continuous member, the parasitic capacitance between the electron barrier layer 24 and the substrate 12 is reduced. When the lower surface of the high resistance buried layer 22 is in contact with the substrate 12 or the first cladding layer 16, the parasitic capacitance is also reduced. By reducing the parasitic capacitance, the optical semiconductor element 10 according to this embodiment can operate at a high speed.

### Embodiment 2

The optical semiconductor element 40 according to Embodiment 2 is the same as that of Embodiment 1, but the difference from Embodiment 1 is that the electron barrier layer 54 is made of p-type or undoped AlInAs. When the electron barrier layer 54 is p-type AlInAs, the dopant is Zn.

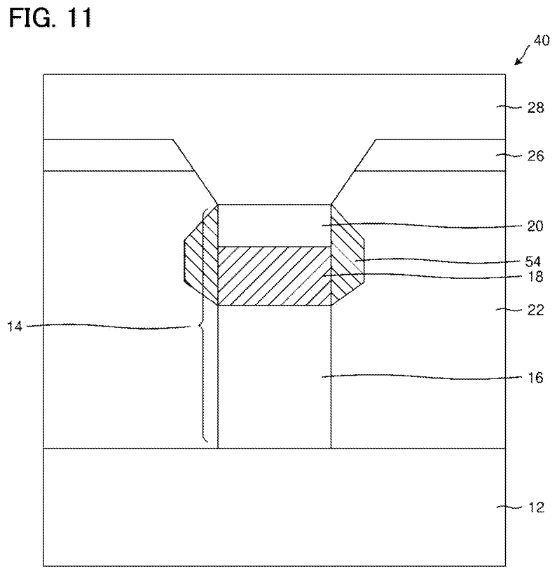

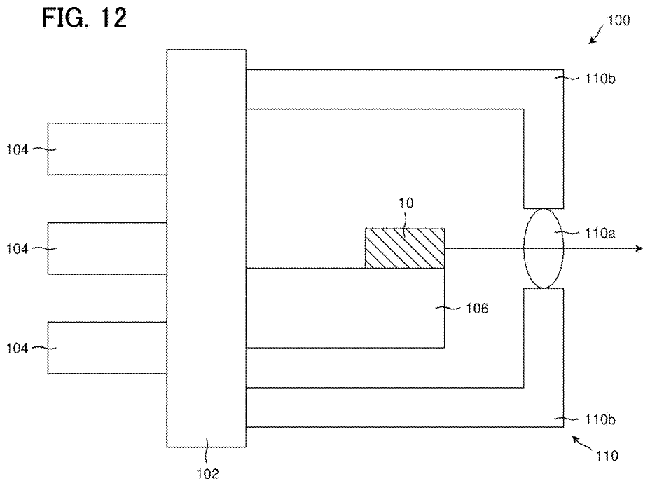

FIG. 11 is a cross-sectional view of an optical semiconductor element 40 according to Embodiment 2. In the optical semiconductor element 40, since the electron barrier layer 54 is made of ternary AlInAs, the physical property can be changed by changing the composition. For example, the band gap can be changed, and the height of the electron barrier of the electron barrier layer 54 with respect to the active layer 18 can be changed. In addition, the electron barrier layer 54 can be formed while maintaining the crystallinity by restricting the lateral growth, which is difficult to adjust the composition in a ternary system such as AlInAs, only to the side surfaces of the mesa 14. When AlInAs is undoped, there is an effect of suppressing diffusion of Zn into the active layer 18 and suppressing formation of a Zn-added p-type region in the vicinity of the active layer 18. Therefore, absorption of light generated in the active layer 18 is suppressed, so that reduction in operating current and improvement in optical output can be expected. When AlInAs is undoped, the diffusion of Zn from the second cladding layer 20 and the contact layer 28 can be further suppressed, so that the controllability of the impurity profile in the cross section of the buried region is also enhanced.

### Embodiment 3

FIG. 12 is a cross-sectional view of an optical module 100 according to Embodiment 3. The optical module 100 has the optical semiconductor element 10 according to Embodiment 1 mounted therein.

The optical module 100 includes a stem 102. The stem 102 is formed of a cold rolled steel plate (SPC).

A plurality of lead pins 104 pass through the stem 102. These lead pins 104 are made of metal. The lead pins 104 protrude into the inside of the optical module 100, but the protrusions are not shown in FIG. 12.

A carrier 106 is fixed to an inner surface of the stem 102. The carrier 106 is made of copper tungsten having a good heat dissipation property in order to dissipate heat generated from the optical semiconductor element 10 to the stem 102.

The optical semiconductor element 10 is mounted on the carrier 106. Although not shown, the optical semiconductor element 10 is electrically connected to the lead pins 104. When the current flowing through the lead pins 104 flows between the contact layer 28 and the substrate 12 in the optical semiconductor element 10, light is generated in the active layer 18, and then laser light is emitted from the optical semiconductor element 10 as indicated by an arrow in FIG. 12. An example of electrical connection between the optical semiconductor element 10 and the lead pins 104 will be described. Two electrodes for applying the above mentioned current to the optical semiconductor device 10 are formed. One lead pin 104 and one electrode of the optical semiconductor element 10 are connected with a bonding wire. Further, the other lead pin 104 is connected to the carrier 106, and the carrier 106 and the other electrode of the optical semiconductor element 10 are connected with a conductive bonding material such as solder.

A lens cap 110 is fixed to the stem 102 so as to enclose the carrier 106 and the optical semiconductor element 10. The lens cap 110 includes a lens 110a that condenses laser light emitted from the optical semiconductor element 10 to emit the laser light to the outside, and a cylindrical cap 110b that fixes the lens 110a. It is this cap 110b that is fixed to the stem 102. The lens 110a is made of glass, and the cap 110b is made of stainless steel (SUS). The internal space formed by the stem 102 and the lens cap 110 is hermetically sealed and filled with nitrogen.

Since the optical module 100 according to Embodiment 3 is equipped with the optical semiconductor element 10 according to Embodiment 1, it is possible to achieve an operation with a low power consumption due to the suppression of the leakage current and a high speed operation due to the reduction of the parasitic capacitance.

Note that the optical semiconductor element to be mounted may be the optical semiconductor element 40 according to Embodiment 2.

### DESCRIPTION OF REFERENCE NUMERALS AND SIGNS

10, 40: optical semiconductor element, 12: substrate, 14: mesa, 16: first cladding layer, 18: active layer, 20: second cladding layer, 22: high resistance buried layer, 22a: first high resistance buried layer, 22b: second high resistance buried layer, 24, 54: electron barrier layer, 26: hole barrier layer, 28: contact layer, 30: mask, 100: optical module, 102: stem, 104: lead pin, 106: carrier, 110: lens cap, 110a: lens, 110b: cap

1. An optical semiconductor element comprising:
a substrate;
a mesa in which a part of a first cladding layer at least, an active layer, and a second cladding layer that are formed on the substrate and stacked in this order from below;
an electron barrier layer formed on both side surfaces of the mesa so as to cover at least side surfaces of the active layer and the second cladding layer, the electron barrier layer serving as an electron barrier with respect to the active layer;
a semi-insulating high resistance buried layer formed on both sides of the mesa so as to bury the mesa and the electron barrier layer; and
a contact layer formed on the second cladding layer, wherein
the high resistance buried layer formed on both the sides of the mesa is a continuous member, and
an entire lower surface of the high resistance buried layer is in contact with the substrate or the first cladding layer.

2. The optical semiconductor element according to claim 1, wherein
the high resistance buried layer is made of InP doped with Fe or Ru, and
the electron barrier layer is made of p-type InP doped with Zn.

3. The optical semiconductor element according to claim 2, wherein a carrier concentration of the electron barrier layer is 2×10¹⁷ cm⁻³ or more.

4. The optical semiconductor element according to claim 1, wherein the electron barrier layer is made of AlInAs.

5. An optical semiconductor element comprising:
a substrate;
a mesa in which a part of a first cladding layer at least, an active layer, and a second cladding layer that are formed on the substrate and stacked in this order from below:
an electron barrier layer formed on both side surfaces of the mesa so as to cover at least side surfaces of the active layer and the second cladding layer, the electron barrier layer serving as an electron barrier with respect to the active layer;
a semi-insulating high resistance buried layer formed on both sides of the mesa so as to bury the mesa and the electron barrier layer; and
a contact layer formed on the second cladding layer, wherein
the high resistance buried layer formed on both the sides of the mesa is a continuous member, and
a lower surface of the high resistance buried layer is in contact with the substrate or the first cladding layer,
wherein, on the side surfaces of the mesa, a lower end of the electron barrier layer is in a range from a lower end of the active layer to a position 0.5 μm lower than the lower end of the active layer.

6. The optical semiconductor element according to claim 1, wherein
the contact layer spreads above the high resistance buried layer, and
a hole barrier layer is formed between the high resistance buried layer and the contact layer to serve as a hole barrier with respect to the contact layer.

7. An optical module comprising:
a stem;
a lead pin passing through the stem;
a carrier fixed to the stem;
the optical semiconductor element according to claim 1 that is fixed to the carrier and is electrically connected to the lead pin; and
a lens cap that includes a lens that condenses laser light emitted from the optical semiconductor element to emit the laser light outside and a cylindrical cap to fix the lens and in which the cap is fixed to the stem so as to enclose the carrier and the optical semiconductor element.

8. A method for manufacturing an optical semiconductor element, the method comprising steps of:
stacking a first cladding layer, an active layer, and a second cladding layer on a substrate in this order;
forming a mesa by etching both sides of a location where the mesa is to be formed from a top surface of the second cladding layer to the substrate is exposed or to a middle of the first cladding layer;
forming a semi-insulating first high resistance buried layer on a top surface of the substrate or a top surface of the first cladding layer exposed by the etching on both sides of the mesa such that an upper end of the first high resistance buried layer on a side surface of the mesa does not extend beyond a lower end of the active layer;
forming an electron barrier layer serving as an electron barrier with respect to the active layer on both side surfaces of the mesa that are exposed;
forming a second high resistance buried layer having the same material and composition as those of the first high resistance buried layer on the first high resistance buried layer so as to bury the mesa and the electron barrier layer; and
forming a contact layer on the second cladding layer.

9. The method for manufacturing an optical semiconductor element according to claim 8, further comprising a step of:
removing a deposition deposited on the first high resistance buried layer when the electron barrier layer is formed, by simultaneously supplying a halogen-based etching gas and a group V gas being the same as that supplied as a raw material gas for the first high resistance buried layer in the step of forming the first high resistance buried layer, between the step of forming the electron barrier layer and the step of forming the second high resistance buried layer, wherein
the first high resistance buried layer is made of a group III-V compound.

10. The method for manufacturing the optical semiconductor element according to claim 8, wherein
the electron barrier layer is made of InP,
in the step of forming the electron barrier layer, a growth temperature of the electron barrier layer is 500 to 600 degrees C., and a flow rate of TMIn supplied as a raw material gas for the electron barrier layer is 2×10⁻⁴ mol/min or more.

11. The method for manufacturing the optical semiconductor element according to claim 8, wherein
the high resistance buried layer is made of InP doped with Fe or Ru, and
the electron barrier layer is made of p-type InP doped with Zn.

12. The method for manufacturing the optical semiconductor element according to claim 11, wherein a carrier concentration of the electron barrier layer is 2×10¹⁷ cm⁻³ or more.

13. The method for manufacturing the optical semiconductor element according to claim 8, wherein the electron barrier layer is made of AlInAs.

14. The method for manufacturing the optical semiconductor element according to claim 8, wherein, in the step of forming the electron barrier layer, a halogen-based etching gas is supplied in addition to a raw material gas for the electron barrier layer.

15. The method for manufacturing the optical semiconductor element according to claim 8, wherein, on the side surface of the mesa, a lower end of the electron barrier layer is in a range from the lower end of the active layer to a position 0.5 μm lower than the lower end of the active layer.

16. The method for manufacturing the optical semiconductor element according to claim 8, further comprising steps of:
forming a hole barrier layer serving as a hole barrier with respect to the contact layer on the second high resistance buried layer between the step of forming the second high resistance buried layer and the step of forming the contact layer, wherein,
in the step of forming the contact layer, the contact layer is formed so as to spread over the hole barrier layer.

17. The optical semiconductor element according to claim 2, wherein
the contact layer spreads above the high resistance buried layer, and
a hole barrier layer is formed between the high resistance buried layer and the contact layer to serve as a hole barrier with respect to the contact layer.

18. The optical semiconductor element according to claim 3, wherein
the contact layer spreads above the high resistance buried layer, and
a hole barrier layer is formed between the high resistance buried layer and the contact layer to serve as a hole barrier with respect to the contact layer.

19. The optical semiconductor element according to claim 5, wherein
the contact layer spreads above the high resistance buried layer, and
a hole barrier layer is formed between the high resistance buried layer and the contact layer to serve as a hole barrier with respect to the contact layer.

20. An optical module comprising:
a stem;
a lead pin passing through the stem;
a carrier fixed to the stem;
the optical semiconductor element according to claim 5 that is fixed to the carrier and is electrically connected to the lead pin; and
a lens cap that includes a lens that condenses laser light emitted from the optical semiconductor element to emit the laser light outside and a cylindrical cap to fix the lens and in which the cap is fixed to the stem so as to enclose the carrier and the optical semiconductor element.
